(19) United States
(12) Patent Application Publication
(10) Pub. No.: US 2025/0223699 A1
(43) Pub. Date: Jul. 10, 2025

(54) SHOWERHEAD STRUCTURE AND APPARATUS FOR TREATING SUBSTRATE

(71) Applicant: Samsung Electronics Co., Ltd., Suwon-si (KR)

(72) Inventors: Tae Seung YU, Suwon-si (KR); Seong June JEONG, Suwon-si (KR); Jae Ho KIM, Suwon-si (KR); Jun Hyung KIM, Suwon-si (KR); Cheol Hun LEE, Suwon-si (KR); Han Byul KANG, Suwon-si (KR); Hyun Seok KANG, Suwon-si (KR); Tae Hee YOO, Suwon-si (KR); Woo Cheol JEONG, Suwon-si (KR)

(21) Appl. No.: 18/817,625

(22) Filed: Aug. 28, 2024

(30) Foreign Application Priority Data
Jan. 4, 2024 (KR) 10-2024-0001382

(51) Int. Cl. C23C 16/455; C23C 16/34; H01J 37/32

(52) U.S. Cl. CPC C23C 16/45565; C23C 16/342; C23C 16/4557; C23C 16/4558; H01J 37/32422; H01J 37/3244; H01J 2237/3321; H01J 2237/3323

(57) ABSTRACT

A showerhead structure comprises a showerhead including an inner zone, an outer zone, and a partitioning wall therebetween and configured to isolate the inner zone and the outer zone from each other. A first plate is on top of the showerhead and includes a distributor. A plurality of first holes is in the inner zone, and a plurality of second holes is in the outer zone. A plurality of columns in each of the inner zone and the outer zone each extending toward the first plate and having a third hole and a first fluid passage connected to the third hole therein. A space under the showerhead receives a fluid through the first fluid passage and the third hole, the space under the showerhead receives a first gas through the first hole, and the space under the showerhead is configured to receive a second gas through the second hole.

### CROSS-REFERENCE TO RELATED APPLICATION

This application claims priority from Korean Patent Application No. 10-2024-0001382 filed on Jan. 4, 2024, in the Korean Intellectual Property Office, and all the benefits accruing therefrom under 35 U.S.C. 119, the contents of which in its entirety are herein incorporated by reference.

### BACKGROUND

### Field

The present disclosure relates to a showerhead structure and a substrate treating apparatus.

### Description of Related Art

In a semiconductor manufacturing process, a substrate treating apparatus is used to treat a substrate such as a semiconductor wafer using plasma.

In the substrate treating apparatus, a treating process such as an etching process or a deposition process is performed using plasma. For this purpose, the substrate treating apparatus includes a showerhead that supplies process gas. Additionally, in a recent semiconductor manufacturing process, the substrate such as a semiconductor wafer is becoming larger, and process uniformity in a treating process within the substrate is becoming more important.

### SUMMARY

A technical purpose of the present disclosure is to provide a showerhead structure with improved uniformity.

A technical purpose of the present disclosure is to provide a substrate treating apparatus with improved uniformity.

The technical challenges in the present disclosure are not limited to the technical challenges mentioned above, and other technical challenges not mentioned will be clearly understood by those skilled in the art from the description below.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

According to an aspect of the present disclosure, there is provided a showerhead structure comprising a showerhead including an inner zone, an outer zone, and a partitioning wall therebetween and configured to isolate the inner zone and the outer zone from each other. A first plate is on top of the showerhead and includes a distributor. A plurality of first holes is in the inner zone, a plurality of second holes is in the outer zone, and a plurality of columns is in each of the inner zone and the outer zone. Each of the plurality of columns extends toward the first plate and has a third hole and a first fluid passage connected to the third hole therein. A space under the showerhead is configured to receive a fluid supplied through the first fluid passage and the third hole, the space under the showerhead is configured to receive a first gas supplied through the first hole, and the space under the showerhead is configured to receive a second gas through the second hole.

According to another aspect of the present disclosure, there is provided a substrate treating apparatus comprising a showerhead including an inner zone, an outer zone, and a partitioning wall therebetween and configured to isolate the inner zone and the outer zone from each other, an ion blocker on top of the showerhead and including a distributor, a plasma generator configured to supply plasma to the ion blocker and a chamber under the showerhead, wherein a substrate support unit configured to support a substrate thereon is in the chamber, and a treating space configured to treat the substrate therein is in the chamber. A plurality of first holes is in the inner zone, and a plurality of second holes is in the outer zone. A plurality of third holes is in each of the inner zone and the outer zone, and a plurality of first fluid passages are directly and respectively connected to the third holes. The plasma generator is configured to generate ions that are removed by the ion blocker, such that radicals in the plasma are supplied to the treating space through the first fluid passage and the plurality of thir holes. The inner zone is configured to receive a first gas which is supplied to the treating space through the plurality of first holes, and the outer zone is configured to receive a second gas which is supplied to the treating space through the plurality of second holes.

According to another aspect of the present disclosure, there is provided a substrate treating apparatus comprising a showerhead including an inner zone, an outer zone, and a partitioning wall therebetween and configured to isolate the inner zone and the outer zone from each other. A first plate is on top of the showerhead and includes a distributor, and a chamber is under the showerhead. A substrate support unit is configured to support a substrate thereon in the chamber, and a treating space is configured to treat the substrate therein in the chamber. A plurality of first holes is in the inner zone, and a plurality of second holes is in the outer zone. A plurality of columns is in each of the inner zone and the outer zone, wherein each of the plurality of columns extends toward the first plate and has a third hole and a first fluid passage connected to the third hole therein The treating space is configured to receive radicals supplied through the first fluid passage and the third hole. The treating space is configured to receive borazine (B₃H₆N₃) supplied through the plurality of first holes and the plurality of second holes. In the treating space, in use, the borazine and the radicals react each other to produce amorphous boron nitride (a-BN).

Specific details of other embodiments are contained in the detailed descriptions and drawings.

### BRIEF DESCRIPTION OF DRAWINGS

The above and other aspects and features of the present disclosure will become more apparent by describing in detail some embodiments thereof with reference to the attached drawings, in which:

FIG. 1 is a schematic layout diagram for illustrating a showerhead structure according to some embodiments,

FIG. 2 is a perspective view for illustrating the showerhead structure in FIG. 1.

FIG. 3 is a perspective view for illustrating the showerhead lower body in FIG. 1.

FIG. 4 is a top view for illustrating the showerhead lower body in FIG. 1.

FIG. 5 is a perspective view for illustrating a column in FIG. 3.

FIG. 6 is a perspective view for illustrating the distributor in FIG. 1.

FIG. 7 is a cross-sectional view showing only a portion of FIG. 1 to illustrate the distributor in FIG. 6.

FIG. 8 is a schematic layout diagram for illustrating an operation and effects of the showerhead structure according to some embodiments.

FIG. 9 is a schematic layout diagram for illustrating the first channel in FIG. 8.

FIG. 10 is a perspective view for illustrating the first line in FIG. 9.

FIG. 11 is a perspective view for illustrating the first manifold in FIG. 9.

FIG. 12 is a schematic layout diagram for illustrating the second channel in FIG. 8.

FIG. 13 is a perspective view for illustrating the second line in FIG. 12.

FIG. 14 is a perspective view for illustrating the second manifold in FIG. 13.

FIG. 15 is a schematic layout diagram for illustrating the third channel in FIG. 8.

FIG. 16 and FIG. 17 are layout diagrams schematically showing a substrate treating apparatus according to some embodiments.

### DETAILED DESCRIPTIONS

Advantages and features of the present disclosure, and a method of achieving the advantages and features will become apparent with reference to embodiments described herein in detail together with the accompanying drawings. However, an embodiment of embodiments of the present disclosure are not limited to the embodiments as disclosed under, but may be implemented in various different forms. Thus, these embodiments are set forth only to make the present disclosure complete, and to entirely inform the scope of the present disclosure to those of ordinary skill in the technical field to which the present disclosure belongs, and the present disclosure is only defined by the scope of the claims.

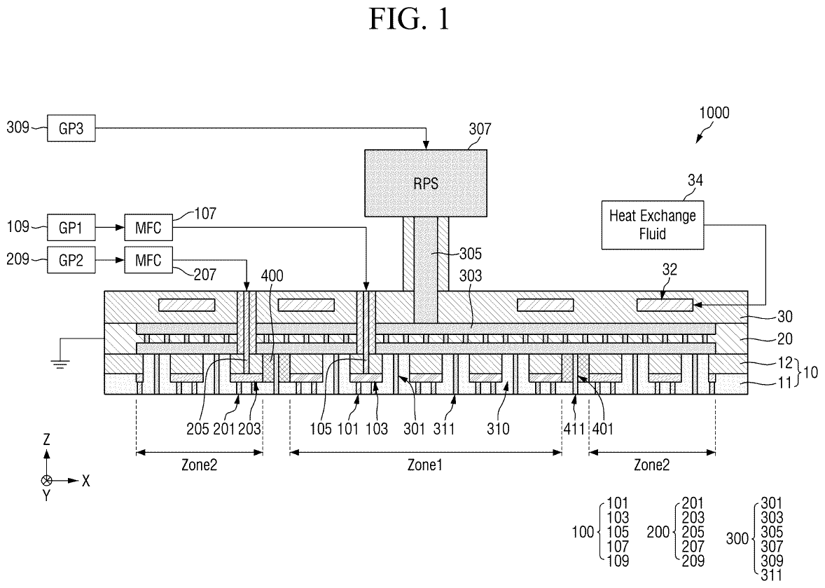

FIG. 1 is a schematic layout diagram for illustrating a showerhead structure according to some embodiments.

Referring to FIG. 1, a showerhead structure 1000 may include a showerhead 10, a first plate 20, and a second plate 30. Furthermore, the showerhead structure 1000 may include a first channel 100, a second channel 200, and a third channel 300.

The showerhead 10 may include a showerhead lower body 11 and a showerhead upper body 12.

The showerhead lower body 11 may be divided into an inner zone Zone1 and an outer zone Zone2 via a partitioning wall 400.

The first plate 20 may be on top of the showerhead 10 and may include a distributor 303. The first plate 20 may be connected to a ground. For example, the first plate 20 may be an ion blocker. Thus, ions contained in the plasma passing through the first plate 20 may be absorbed to the ground. That is, only radicals contained in the plasma may be selectively supplied to the showerhead 10.

Thus, a wide process window can be secured, and synthesis of a material with ultra-low dielectric constant can be achieved.

The second plate 30 may be on top of the first plate 20 and may include a heat exchange unit 32. The heat exchange unit 32 may be connected to a heat exchange fluid supply 34 and may receive fluid therefrom. Thus, a temperature of the fluid passing through the second plate 30 may be adjusted.

The first channel 100 may include a plurality of first holes 101, an inner plate 103, a first line 105, a first flow rate control module 107 and a first gas supply 109.

The plurality of first holes 101 may be connected to the inner plate 103 of the showerhead lower body 11.

The first line 105 may connect the inner zone Zone1 and the first flow rate control module 107 to each other. The first flow rate control module 107 may control a flow rate of first gas supplied from the first gas supply 109. Thus, the inner zone Zone1 may receive the first gas from the first gas supply 109. For example, the first gas may be borazine (B₃H₆N₃) as a precursor for thin film deposition. However, embodiments of the present disclosure are not limited thereto.

The first line 105 may include a plurality of configurations. A detailed description of each of the configurations is provided herein.

The second channel 200 may include a plurality of second holes 201, a second line 205, a second flow rate control module 207, and a second gas supply 209.

The plurality of second holes 201 may be in the outer plate 203 of the showerhead lower body 11.

The second line 205 may connect the outer zone Zone2 and the second flow rate control module 207 to each other. The second flow rate control module 207 may control a flow rate of second gas supplied from the second gas supply 209. Thus, the outer zone Zone2 may receive the second gas from the second gas supply 209. For example, the second gas may be borazine (B₃H₆N₃) as a precursor for thin film deposition. However, the embodiments of the present disclosure are not limited thereto.

The second line 205 may include a plurality of configurations. A detailed description of each of the configurations is provided herein.

Amounts of the first gas and the second gas supplied along the first channel 100 and the second channel 200 by the first gas supply 109 and the second gas supply 209 may be controlled by the first flow rate control module 107 and the second flow rate control module 207, respectively.

Individually controlling the amounts of the gases respectively supplied through the inner zone Zone1 and the outer zone Zone2 of the showerhead lower body 11 may allow the gases to be supplied uniformly from the first hole 101 and the second hole 201 of the showerhead lower body 11.

In the drawing, the first channel 100 and the second channel 200 are shown as being connected to the first gas supply 109 and the second gas supply 209, respectively. However, embodiments of the present disclosure are not limited thereto.

For example, in some embodiments, the first channel 100 and the second channel 200 may be connected to one gas supply. Amounts of gases respectively supplied along the first channel 100 and the second channel 200 from the gas supply may be controlled by the first flow rate control module 107 and the second flow rate control module 207, respectively.

The third channel 300 may include a plurality of third holes 311, a plurality of first fluid passages 301, a plurality of fourth holes 411, a plurality of second fluid passages 401, a distributor 303, a third line 305, a plasma generator 307, and a third gas supply 309.

The plurality of third holes 311 and the plurality of first fluid passages 301 may be in a plurality of columns 310 on top of each of the inner zone Zone1 and the outer zone Zone2 of the showerhead lower body 11. The plurality of columns 310 may have a protruding shape toward the first plate 20. The plurality of first fluid passages 301 may be connected to the plurality of third holes 311 and the distributor 303.

The plurality of fourth holes 411 and the plurality of second fluid passages 401 may be in the partitioning wall 400. The plurality of second fluid passages 401 may be connected to the plurality of fourth holes 411 and the distributor 303.

The distributor 303 may uniformly supply the fluid supplied along the third line 305 to the plurality of third holes 311 and the plurality of fourth holes 411. For example, the fluid may be plasma. A specific configuration and operation of the distributor 303 is described herein.

The third line 305 may supply plasma generated from the plasma generator 307 or third gas supplied from the third gas supply 309 to the distributor 303.

For example, the third gas may be a mixture of H₂, N₂, and Ar. However, embodiments of the present disclosure are not limited thereto.

The plasma generator 307 may generate plasma from the third gas supplied from the third gas supply 309. For example, the third gas may be a mixture of H₂, N₂, and Ar. However, embodiments of the present disclosure are not limited thereto.

Thus, the gas or the plasma may be supplied along the plurality of third holes 311, the plurality of first fluid passages 301, the plurality of fourth holes 411, and the plurality of second fluid passages 401. For example, the plasma generator 307 may be embodied as a remote plasma source (RPS). However, embodiments of the present disclosure are not limited thereto. For example, the plasma generator 307 may be embodied as an inductively coupled plasma (ICP) generator.

Separating the third channel 300 which supplies plasma to a space under the showerhead structure 1000, and the first channel 100 and the second channel 200 which supply the precursors to a space under the showerhead structure 1000 may allow exposure of the precursor to the plasma to be minimized, thereby securing a wide process window.

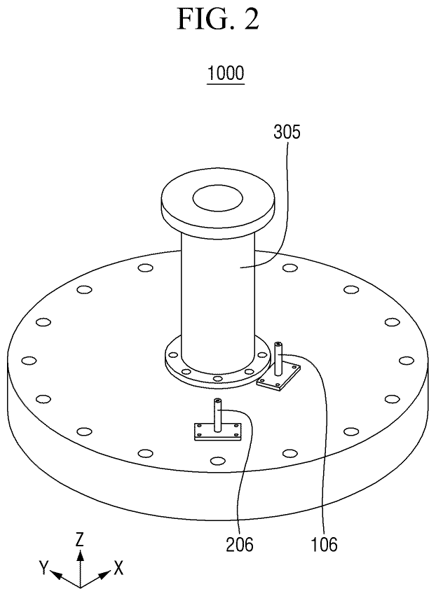

FIG. 2 is a perspective view for illustrating the showerhead structure in FIG. 1.

Referring to FIG. 1 and FIG. 2, the showerhead structure 1000 may include a first inlet 106, a second inlet 206, and the third line 305 on an upper surface thereof.

The first inlet 106 may be connected to the first gas supply (not shown) and the first flow rate control module (not shown). The first gas supplied through the first inlet 106 may be supplied to the space under the showerhead structure 1000 through the first hole 101.

The second inlet 206 may be connected to the second gas supply (not shown) and the second flow rate control module (not shown). The second gas supplied through the second inlet 206 may be supplied to the space under the showerhead structure 1000 through the second hole 201.

The third line 305 may be connected to the third gas supply (not shown). The fluid supplied through the third line 305 may be supplied to the space under the showerhead structure 1000 through the third hole 311 and the fourth hole 411.

In some embodiments, the first inlet 106 and the second inlet 206 may supply borazine (B₃H₆N₃) as a precursor of amorphous boron nitride (a-BN) to the showerhead structure 1000. The third line 305 may supply the plasma to the showerhead structure 1000.

In this configuration, the plasma and the precursor may be supplied to the showerhead structure 1000 through separate and independent channels, such that exposure of the precursor to the plasma may be minimized. Thus, high-quality thin film synthesis may be achieved.

Furthermore, the precursors respectively supplied through the first inlet 106 and the second inlet 206 may be supplied to the inner zone Zone1 and the outer zone Zone2 of the showerhead lower body 11, respectively. In other words, the flow rates of the precursors respectively supplied to the inner zone Zone1 and the outer zone Zone2 may be controlled separately. This may control a distribution of a thickness of a thin film deposited on the substrate by the showerhead structure 1000, thereby achieving high-quality thin film synthesis.

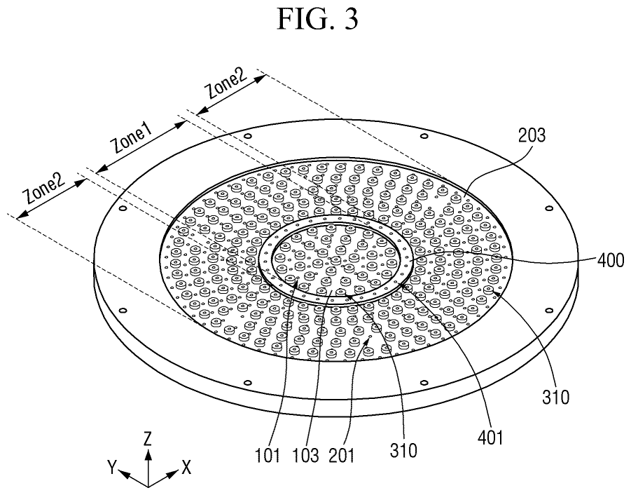

FIG. 3 is a perspective view for illustrating the showerhead lower body in FIG. 1.

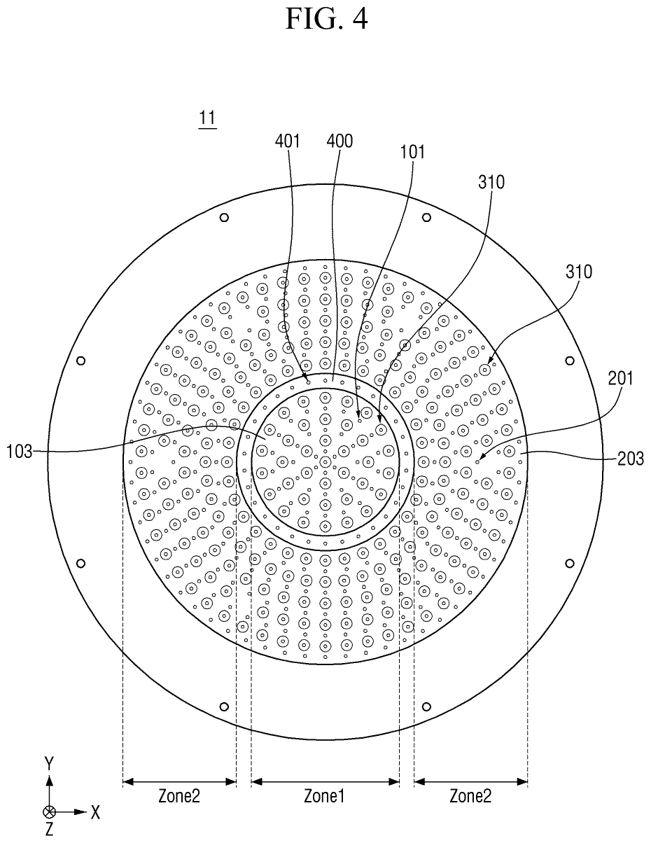

FIG. 4 is a top view for illustrating the showerhead lower body in FIG. 1.

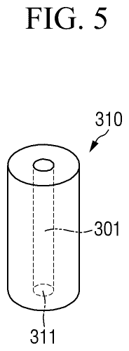

FIG. 5 is a perspective view for illustrating a column in FIG. 3.

Referring to FIG. 1 and FIG. 3 to FIG. 5, the showerhead lower body 11 may include the inner zone Zone1 and the outer zone Zone2 that are isolated from each other via the partitioning wall 400.

The inner zone Zone1 may include the inner plate 103 of the showerhead lower body 11. The outer zone Zone2 may include the outer plate 203 of the showerhead lower body 11.

The inner zone Zone1 may include the plurality of first holes 101 and the plurality of columns 310.

The outer zone Zone2 may include the plurality of second holes 201 and the plurality of columns 310.

The first gas supplied to the inner zone Zone1 along the first line 105 may be supplied to the space under the showerhead structure through the first hole 101.

The second gas supplied to the outer zone Zone2 along the second line 205 may be supplied to the space under the showerhead structure through the second hole 201.

In some embodiments, the first gas and the second gas may be the same. However, an embodiment of the present disclosure is not limited thereto, and the first gas and the second gas may be different from each other.

Furthermore, the first gas and the second gas may be a precursor for thin film deposition. For example, both the first gas and the second gas may be borazine (B₃H₆N₃), However, embodiments of the present disclosure are not limited thereto.

The plurality of columns 310 may have the plurality of third holes 311 and the plurality of first fluid passages 301 therein. Each of the plurality of third holes 311 may be in a bottom of each of the plurality of columns 310 in a first direction Z. Each of the plurality of first fluid passages 301 may extend in a height direction of each of the plurality of column 310.

The partitioning wall 400 may have the plurality of fourth holes 411 and the plurality of second fluid passages 401 therein. The plurality of fourth holes 411 may be in a bottom of the partitioning wall 400 in the first direction Z. The plurality of second fluid passages 401 may extend in a height direction of the partitioning wall 400.

In some embodiments, a height of the partitioning wall 400 may be the same as that of each of the plurality of columns 310. That is, a height of the first fluid passage 301 and a height of the second fluid passage 401 may be equal to each other.

The fluid supplied to the first fluid passage 301 and the second fluid passage 401 along the distributor 303 may be supplied to the space under the showerhead lower body 11 through the third hole 311 and fourth hole 411.

In some embodiments, the inner zone Zone1 and the outer zone Zone2 may be isolated from each other via the partitioning wall 400, so that the flow rates of the gases respectively supplied to the inner zone Zone1 and the outer zone Zone2 are controlled to be different from each other. Thus, the amounts of the gases respectively supplied through the first hole 101 and the second hole 201 in the inner zone Zone1 and outer zone Zone2 having different areas may be unform. Thus, the thickness distribution of the thin film deposited on the substrate by the showerhead structure 1000 may be uniform, such that high quality thin film synthesis may be achieved.

Furthermore, in some embodiments, all of the first hole 101 to the fourth hole 411 of the showerhead structure 1000 may be entirely open. A size of each of the holes may be finely controlled, such that uniform fluid supply may be achieved in a low flow rate process. Thus, high-quality thin film synthesis may be achieved.

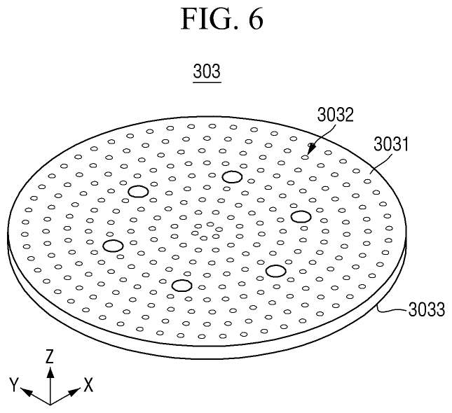

FIG. 6 is a perspective view for illustrating the distributor in FIG. 1.

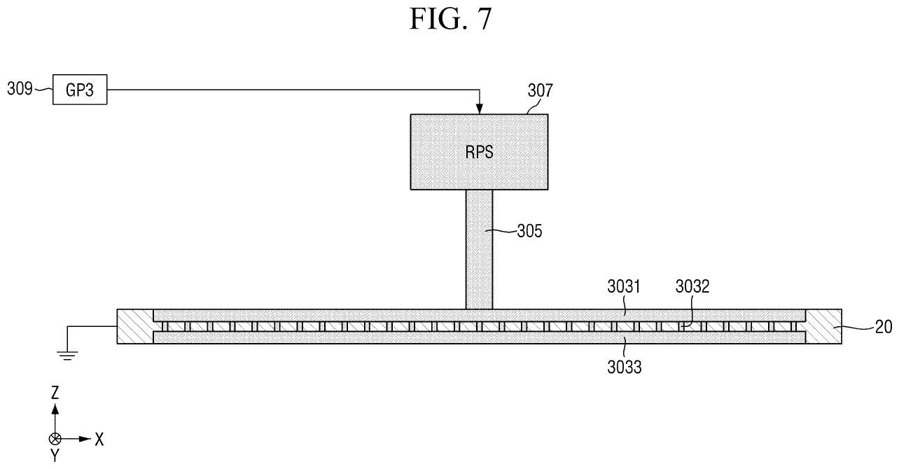

FIG. 7 is a cross-sectional view showing only a portion of FIG. 1 to illustrate the distributor in FIG. 6.

Referring to FIG. 1, FIG. 6 and FIG. 7, the distributor 303 may be in the first plate 20. The distributor 303 may include a first distribution plate 3031, a plurality of distribution holes 3032, and a second distribution plate 3033. The first distribution plate 3031 may be connected to the third line 305 and the plurality of distribution holes 3032. The first distribution plate 3031 may allow the fluid supplied from the third line 305 to be uniformly distributed within the first distribution plate 3031 and may supply the fluid to the plurality of distribution holes 3032.

The second distribution plate 3033 may be connected to the plurality of distribution holes 3032 and the first fluid passage 301 and the second fluid passage 401. A height of the distribution hole 3032 may be equal to a distance between the first distribution plate 3031 and the second distribution plate 3033. The second distribution plate 3033 may allow the fluid supplied from the plurality of distribution holes 3032 to be uniformly distributed within the second distribution plate 3033, and may supply the fluid to the plurality of first fluid passages 301 and the plurality of second fluid passages 401.

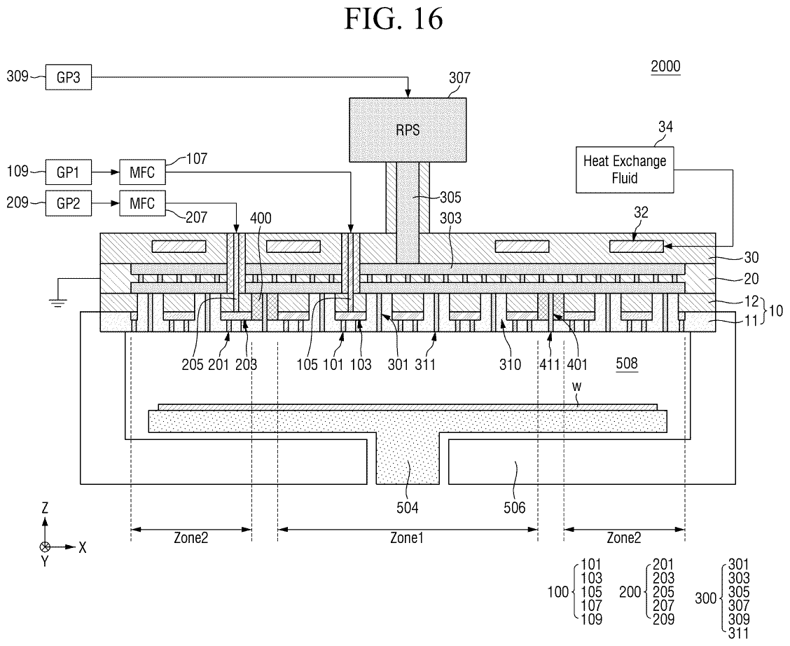

Thus, the fluid may be uniformly supplied to a treating space (508 in FIG. 16) of the chamber through the third channel 300.

In some embodiments, the first plate 20 may be connected to a ground. For example, the first plate 20 may be an ion blocker. Thus, ions contained in the plasma passing through the distributor 303 may be absorbed to the ground, while only radicals may pass through the distributor 303 and be supplied to the plurality of first fluid passages 301 and the plurality of second fluid passages 401. Accordingly, a mild plasma environment may be created in the treating space (508 in FIG. 16) of a chamber.

Creating the mild plasma environment may allow a material with an ultra-low dielectric constant to be synthesized.

For example, borazine (B₃H₆N₃) as the precursor may be decomposed by the radicals in the treating space 508 of the chamber to generate amorphous boron nitride (a-BN).

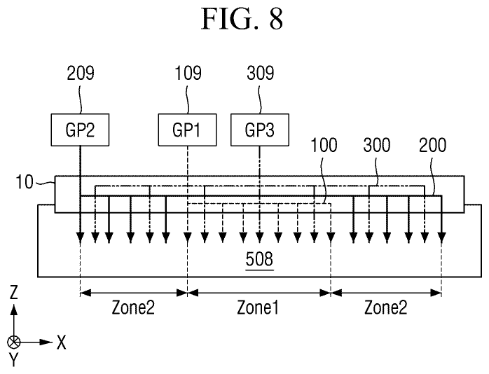

FIG. 8 is a schematic layout diagram for illustrating an operation and effects of the showerhead structure according to some embodiments.

Referring to FIG. 1 and FIG. 8, the showerhead structure 1000 may supply fluid through the first channel 100, the second channel 200, and the third channel 300. Additionally, the showerhead lower body 11 may be divided into the inner zone Zone1 and the outer zone Zone2 via the partitioning wall 400.

The first gas generated in the first gas supply 109 may be supplied to the treating space (508 in FIG. 16) of the chamber through the first channel 100. The second gas generated in the second gas supply 209 may be supplied to the treating space 508 of the chamber through the second channel 200.

In some embodiments, the first gas and the second gas may be the precursors for thin film deposition. For example, the first gas and the second gas may be borazine. However, embodiments of the present disclosure are not limited thereto.

The first channel 100 may control the flow rate of the gas to be supplied to the inner zone Zone1 of the showerhead 10. The second channel 200 may control the flow rate of the gas to be supplied to the outer zone Zone2 of the showerhead 10. In this configuration, individually controlling the amounts of the gases respectively supplied to the inner zone Zone1 and the outer zone Zone2 of the showerhead 10 having different areas may allow the gas to be supplied uniformly from the first hole 101 and the second hole 201 of the showerhead structure 1000. Thus, the distribution of the thickness of the thin film deposited on the substrate by the showerhead structure 1000 may be controlled to be uniform, thereby achieving high-quality thin film synthesis.

The third gas generated in the third gas supply 309 may be supplied to the treating space 508 of the chamber through the third channel 300.

In some embodiments, the third gas may be gas for plasma generation. For example, the third gas may be a mixture of H₂, N₂, and Ar. However, embodiments of the present disclosure are not limited thereto.

In this configuration, separating the third channel 300 which supplies the plasma to the treating space 508 under the showerhead structure 1000, and the first channel 100 and the second channel 200 which supply the precursor to the treating space 508 under the showerhead structure 1000 may allow exposure of the precursor to the plasma to be minimized, thereby securing a wide process window.

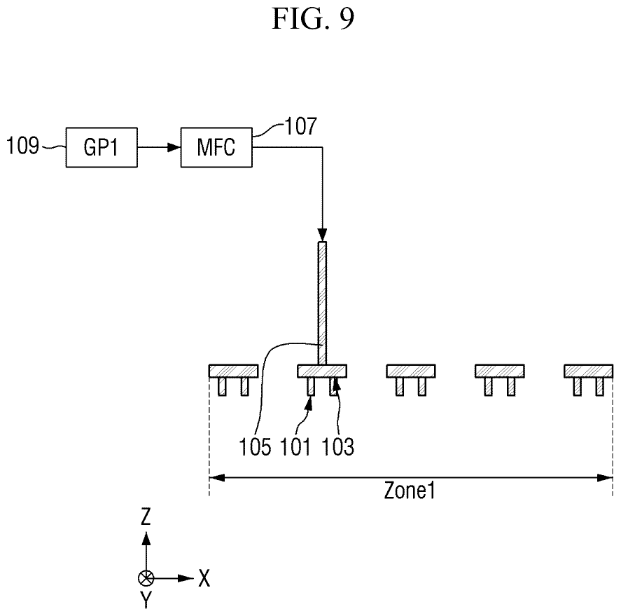

FIG. 9 is a schematic layout diagram for illustrating the first channel in FIG. 8.

Referring to FIG. 9, the first channel 100 may include the plurality of first holes 101 and the inner plate 103 included in the inner zone Zone1 of the showerhead lower body 11, the first line 105, the first flow rate control module 107 and the first gas supply 109.

The plurality of first holes 101 may be in the inner zone Zone1 of the showerhead lower body 11.

The first gas supplied from the first flow rate control module 107 may be supplied through the first line 105 to the inner zone Zone1. The first line 105 may include a plurality of configurations. A detailed description of each configuration is provided herein.

The first flow rate control module 107 may control the flow rate of the first gas supplied from the first gas supply 109. Thus, the inner zone Zone1 may receive the first gas from the first gas supply 109.

In some embodiments, the first gas may be the precursor for thin film deposition. For example, the first gas may be borazine (B₃H₆N₃). However, embodiments of the present disclosure are not limited thereto.

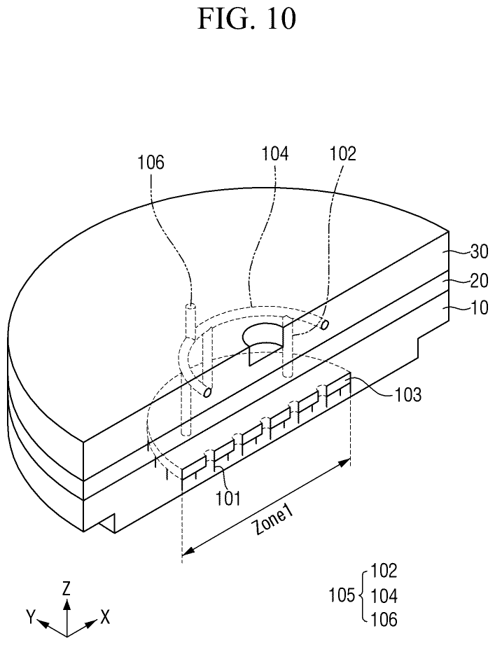

FIG. 10 is a perspective view for illustrating the first line in FIG. 9.

Referring to FIG. 9 and FIG. 10, the first line 105 may include the first inlet 106, a first manifold 104, and a plurality of first branch pipes 102.

The first inlet 106 may be on top of an upper surface of the second plate 30 and may supply the first gas supplied from the first gas supply 109 and the first flow rate control module 107 to the showerhead structure 1000.

The first manifold 104 may be on top of the first plate 20, and may be constructed such that the first gas may be distributed within the first manifold 104, and thus the first gas supplied from the first inlet 106 may be uniformly supplied therethrough to the plurality of first branch pipes 102. A specific construction of the first manifold 104 will be described herein.

The plurality of first branch pipes 102 may uniformly supply the first gas to the inner zone Zone1.

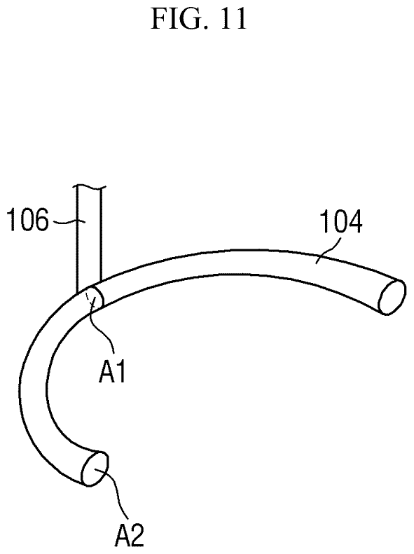

FIG. 11 is a perspective view for illustrating the first manifold in FIG. 9.

Referring to FIG. 11, a cross-sectional area of the first manifold 104 may vary depending on a varying position having a varying distance from the first inlet 106.

In some embodiments, the cross-sectional area thereof at a position closest to the first inlet 106 may be A1. The cross-sectional area thereof at a position far from the first inlet 106 may be A2. For example, A2 may be larger than A1.

Varying the cross-sectional area of the first manifold 104 depending on a varying position having a varying distance from the first inlet 106 may allow the first gas to be uniformly distributed within the first manifold 104 regardless of the varying position having the varying distance from the first inlet 106. Accordingly, a cross-sectional area of the first manifold 104 increases as the first manifold 104 extends away from the first inlet 106.

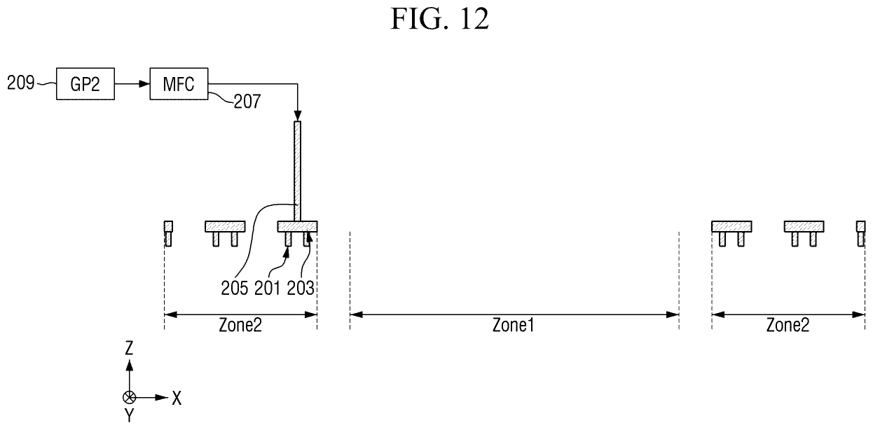

FIG. 12 is a schematic layout diagram for illustrating the second channel in FIG. 8.

Referring to FIG. 12, the second channel 200 may include the plurality of second holes 201 and the outer plate 203 included in the outer zone Zone2 of the showerhead lower body 11, the second line 205, the second flow rate control module 207 and the second gas supply 209.

The plurality of second holes 201 may be in the outer zone Zone2 of the showerhead lower body 11.

The second gas supplied from the second flow rate control module 207 may be supplied to the outer zone Zone2 through the second line 205. The second line 205 may include a plurality of configurations. A detailed description of each configuration is provided herein.

The second flow rate control module 207 may control the flow rate of the second gas supplied from the second gas supply 209. Thus, the outer zone Zone2 may receive the second gas from the second gas supply 209.

In some embodiments, the second gas may be the precursor for thin film deposition. For example, the second gas may be borazine (B₃H₆N₃). However, embodiments of the present disclosure are not limited thereto.

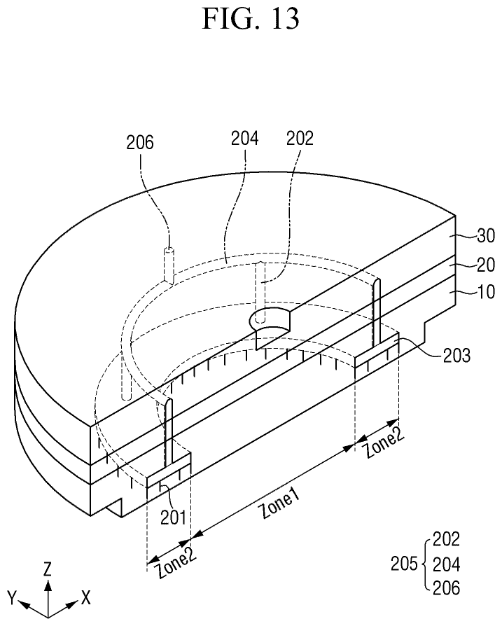

FIG. 13 is a perspective view for illustrating the second line in FIG. 12.

Referring to FIG. 12 and FIG. 13, the second line 205 may include the second inlet 206, a second manifold 204, and a plurality of second branch pipes 202.

The second inlet 206 may be on top of the upper surface of the second plate 30 and may supply the second gas supplied from the second gas supply 209 and the second flow rate control module 207 to the showerhead structure 1000.

The second manifold 204 may be on top of the first plate 20 and may be constructed such that the second gas may be distributed within the second manifold 204, and thus the second gas supplied from the second inlet 206 may be uniformly supplied therethrough to the plurality of second branch pipes 202. A specific construction of the second manifold 204 is described herein.

The plurality of second branch pipes 202 may uniformly supply the second gas to the outer zone Zone2.

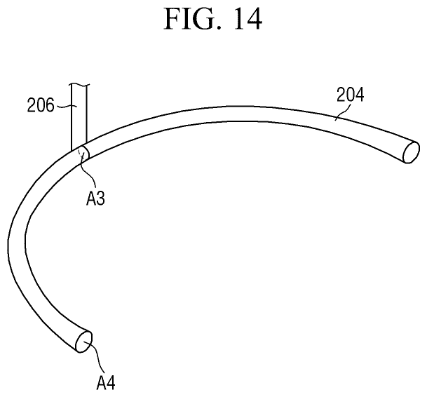

Referring to FIG. 14, a cross-sectional area of the second manifold 204 may vary depending on a varying position having a varying distance from the second inlet 206.

FIG. 14 is a perspective view for illustrating the second manifold in FIG. 13.

In some embodiments, the cross-sectional area thereof at a position closest to the second inlet 206 may be A3. The cross-sectional area thereof at a position far from the second inlet 206 may be A4. For example, A4 may be larger than A3.

Varying the cross-sectional area of the second manifold 204 depending on a varying position having a varying distance from the second inlet 206 may allow the second gas to be uniformly distributed within the second manifold 204 regardless of the varying position having the varying distance from the second inlet 206. Accordingly, a cross-sectional area of the second manifold 204 increases as the second manifold 204 extends away from the second inlet 206.

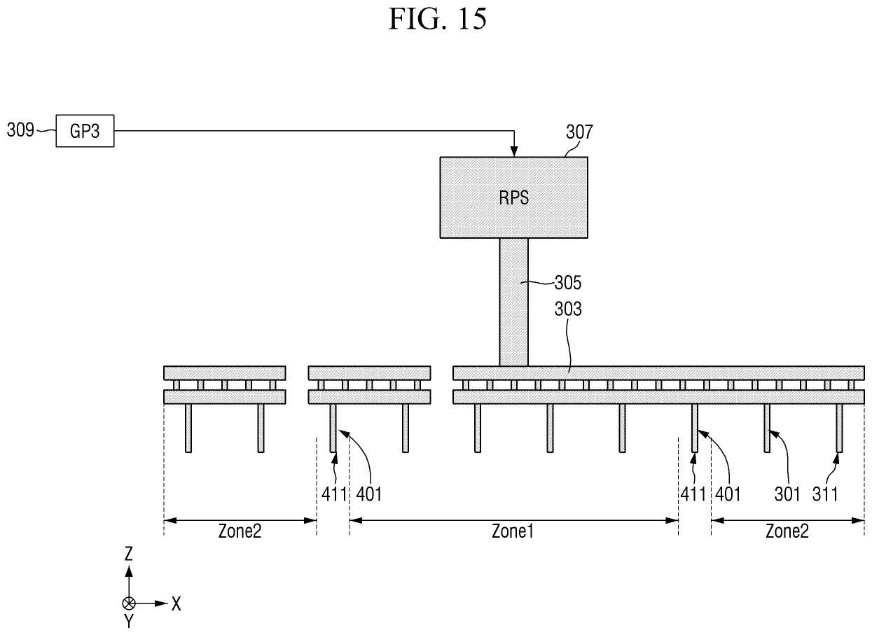

FIG. 15 is a schematic layout diagram for illustrating the third channel in FIG. 8.

Referring to FIG. 15, the third channel 300 may include the plurality of third holes 311 and the plurality of first fluid passages 301. The plurality of third holes 311 and the plurality of first fluid passages 301 may be arranged in each of the inner zone Zone1 and the outer zone Zone2 of the showerhead lower body 11.

The third channel 300 may include the plurality of fourth holes 411 and the plurality of second fluid passages 401. The plurality of fourth holes 411 and the second fluid passage 401 may be within the partitioning wall 400 between the inner zone Zone1 and the outer zone Zone2 of the showerhead lower body 11.

Furthermore, the third channel 300 may include the distributor 303, the third line 305, the plasma generator 307, and the third gas supply 309.

The distributor 303 may connect the plurality of first fluid passages 301 and the third line 305 to each other, and may connect the plurality of second fluid passages 401 and the third line 305 to each other. As described above in FIG. 6 and FIG. 7, the distributor 303 may uniformly distribute to the fluid supplied along the third line 305 to the plurality of first fluid passages 301 and the plurality of second fluid passages 401. For example, the fluid may be plasma.

The third line 305 may connect the plasma generator 307 and the distributor 303 to each other.

The plasma generator 307 may generate plasma from the third gas supplied from the third gas supply 309. For example, the plasma generator 307 may be embodied as a remote plasma source (RPS). However, embodiments of the present disclosure are not limited thereto. For example, the plasma generator 307 may be embodied as an inductively coupled plasma (ICP) generator.

The third gas supply 309 may supply the third gas to the plasma generator 307. For example, the third gas may be a mixture of H₂, N₂, and Ar. However, embodiments of the present disclosure are not limited thereto.

In this configuration, separating the third channel 300 which supplies the plasma to the treating space 508 under the showerhead structure 1000, and the first channel 100 and the second channel 200 which supply the precursor to the treating space 508 under the showerhead structure 1000 may allow exposure of the precursor to the plasma to be minimized, thereby securing a wide process window.

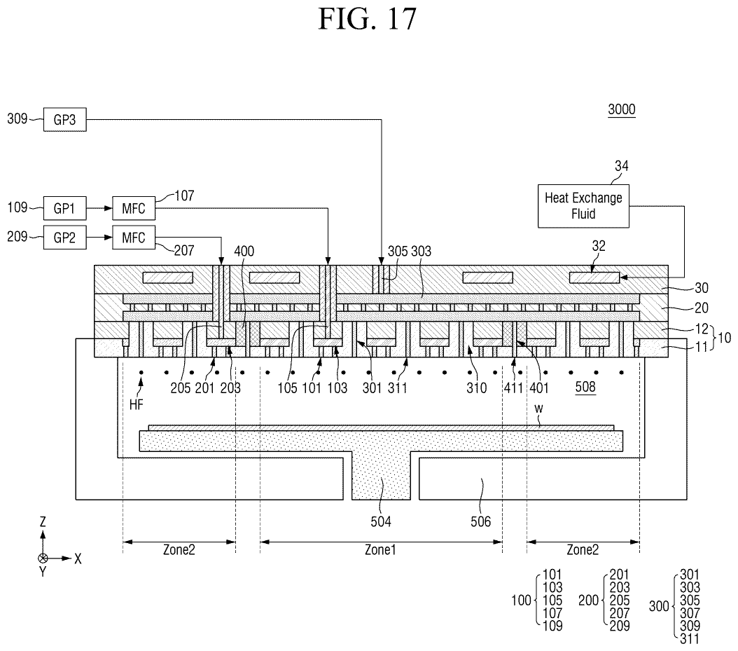

FIG. 16 and FIG. 17 are layout diagrams schematically showing a substrate treating apparatus according to some embodiments. FIG. 16 and FIG. 17 are diagrams showing a substrate treating apparatus in which a chamber is combined with the showerhead structure in FIG. 1. For convenience of description, the contents as described above with reference to FIG. 1 are omitted.

Referring to FIG. 16, the substrate treating apparatus 2000 may include the showerhead structure 1000 and the chamber. In the chamber, the treating space 508 may be defined by a housing 506. For example, the substrate treating apparatus may be configured to perform PECVD (Plasma Enhanced Chemical Vapor Deposition). However, the present disclosure is not limited thereto.

In some embodiments, the chamber may include a substrate support unit 504. The substrate support unit 504 may support the substrate W placed on an upper surface thereof.

In some embodiments, the substrate treating apparatus 2000 may generate a thin film deposition material under reaction of the radicals and the precursor in the treating space 508 of the chamber.

In some embodiments, the radicals may be supplied to the treating space 508 through the third channel 300.

For example, the third gas supply 309 may supply a mixed gas of H₂, N₂, and Ar to the treating space 508. The plasma generator 307 may generate plasma from the mixed gas. The ions contained in the plasma supplied to the distributor 303 may be filtered out through the ground connected to the first plate 20. Only the radicals may be supplied to the treating space 508 through the first fluid passage 301 and the second fluid passage 401.

In some embodiments, the precursor may be supplied to the treating space 508 through the first channel 100 and the second channel 200.

For example, the first gas supply 109 and the second gas supply 209 may supply borazine (B₃H₆N₃) to the treating space 508.

In some embodiments, the radicals and the precursor react with each other within the treating space 508 to synthesize a material with an ultra-low dielectric constant.

For example, the amorphous boron nitride (a-BN) with an ultra-low dielectric constant may be produced through the reaction of the radicals and borazine (B₃H₆N₃).

In this configuration, individually supplying the plasma and the precursor through separate and independent channels may allow exposure of the precursor to the plasma to be minimized. Thus, high-quality thin film synthesis may be achieved.

Furthermore, the first channel 100 may control the flow rate of gas supplied through the inner zone Zone1 of the showerhead structure 1000. The second channel 200 may control the flow rate of gas supplied through the outer zone Zone2 of the showerhead structure 1000. In this configuration, individually controlling the amounts of the gases respectively supplied to the inner zone Zone1 and the outer zone Zone2 of the showerhead 10 having different areas may allow the gas to be supplied uniformly from the first hole 101 and the second hole 201 of the showerhead structure 1000. Thus, the distribution of the thickness of the thin film deposited on the substrate by the showerhead structure 1000 may be controlled to be uniform, thereby achieving high-quality thin film synthesis.

Referring to FIG. 17, a substrate treating apparatus 3000 may include the showerhead structure 1000 and the chamber. In the chamber, the treating space 508 may be defined by the housing 506. For example, the substrate treating apparatus may be configured to perform iCVD (Initiated Chemical Vapor Deposition).

In some embodiments, the chamber may include the substrate support unit 504. The substrate support unit 504 may support the substrate W placed on the upper surface thereof.

In some embodiments, the substrate treating apparatus 3000 may generate a thin film deposition material under reaction of an initiator and the precursor in the treating space 508 of the chamber.

In some embodiments, synthesis of a thin film deposition material may be achieved according to a following sequence.

The initiator may be supplied to the treating space 508 through the third channel 300. For example, the third gas supply 309 may supply tert-butyl peroxide (TBPO) to the treating space 508.

The initiator may be decomposed by a filament HF in the treating space 508.

The precursors may be supplied to the treating space 508 through the first channel 100 and the second channel 200. For example, the first gas supply 109 and the second gas supply 209 may supply divinylbenzene (DVB) to the treating space 508.

The initiator decomposed by the filament HF and the precursor may react with each other within the treating space 508 to synthesize a thin film deposition material.

Furthermore, in some embodiments, synthesis of the thin film deposition material may be performed according to a following sequence.

The initiator may be supplied to the treating space 508 through the third channel 300. For example, the third gas supply 309 may supply TBPO to the treating space 508.

The precursor may be supplied to the treating space 508 through the first channel 100 and the second channel 200. For example, the first gas supply 109 and the second gas supply 209 may supply DVB to the treating space 508.

When a pressure in the treating space 508 is stabilized, the filament HF may operate to decompose the initiator.

The initiator decomposed by the filament HF and the precursor may react with each other within the treating space 508 to synthesize a thin film deposition material.

In this configuration, the first channel 100 may control the flow rate of the gas supplied through the inner zone Zone1 of the showerhead structure 1000. The second channel 200 may control the flow rate of the gas supplied through the outer zone Zone2 of the showerhead structure 1000. In this configuration, individually controlling the amounts of the gases respectively supplied to the inner zone Zone1 and the outer zone Zone2 of the showerhead 10 having different areas may allow the gas to be supplied uniformly from the first hole 101 and the second hole 201 of the showerhead structure 1000. Thus, the distribution of the thickness of the thin film deposited on the substrate by the showerhead structure 1000 may be controlled to be uniform, thereby achieving high-quality thin film synthesis.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. A showerhead structure comprising:
a showerhead including an inner zone, an outer zone, and a partitioning wall therebetween, the partitioning wall being configured to isolate the inner zone and the outer zone from each other; and
a first plate on top of the showerhead and including a distributor,
a plurality of first holes in the inner zone of the showerhead,
a plurality of second holes in the outer zone of the showerhead,
a plurality of columns in each of the inner zone and the outer zone, wherein each of the plurality of columns extends toward the first plate and has a third hole and a first fluid passage connected to the third hole therein,
wherein a space under the showerhead is configured to receive a fluid supplied through the first fluid passage and the third hole,
wherein the space under the showerhead is configured to receive a first gas supplied through the first hole,
wherein the space under the showerhead is configured to receive a second gas supplied through the second hole.

2. The showerhead structure of claim 1, wherein the first gas and the second gas are a same gas.

3. The showerhead structure of claim 2, wherein each of the first gas and the second gas is borazine (B₃N₃H₆).

4. The showerhead structure of claim 1, wherein the partitioning wall has:
a plurality of fourth holes at a bottom thereof; and
a plurality of second fluid passages and respectively connected to the plurality of fourth holes,
wherein the space under the showerhead is configured to receive the fluid supplied through the fourth hole and the second fluid passage.

5. The showerhead structure of claim 4, further comprising a plasma generator connected to the distributor through a third line and configured to generate plasma using a third gas supplied from a third gas supply,
wherein the first fluid passage and the plurality of second fluid passages are connected to the distributor.

6. The showerhead structure of claim 5, wherein the first plate is connected to a ground configured to remove ions from the plasma having passed through the distributor.

7. The showerhead structure of claim 6, wherein the fluid is a radical in the plasma.

8. The showerhead structure of claim 1, wherein the inner zone receives the first gas through a first line connected to a first gas supply,
wherein a first inlet of the first line is connected to a first manifold on top of the first plate,
wherein the first manifold is connected to a plurality of first branch pipes extending through the first plate and connected to the inner zone.

9. The showerhead structure of claim 8, wherein the outer zone receives the second gas through a second line connected to a second gas supply,
wherein a second inlet of the second line is connected to a second manifold on top of the first plate,
wherein the second manifold is connected to a plurality of second branch pipes extending through the first plate and connected to the outer zone.

10. The showerhead structure of claim 9, wherein a cross-sectional area of the first manifold increases as the first manifold extends away from the first inlet,
wherein a cross-sectional area of the second manifold increases as the second manifold extends away from the second inlet.

11. The showerhead structure of claim 1, further comprising a second plate on top of the first plate,
wherein the second plate includes a heat exchanger configured to control a temperature of the fluid passing through the second plate.

12. A substrate treating apparatus comprising:
a showerhead including an inner zone, an outer zone, and a partitioning wall therebetween and configured to isolate the inner zone and the outer zone from each other;
an ion blocker on top of the showerhead and including a distributor;
a plasma generator configured to supply plasma to the ion blocker; and
a chamber under the showerhead, wherein a substrate support unit configured to support a substrate thereon is in the chamber, and a treating space configured to treat the substrate therein is in the chamber,
a plurality of first holes in the inner zone,
a plurality of second holes in the outer zone,
a plurality of third holes in each of the inner zone and the outer zone, wherein a plurality of first fluid passages are directly and respectively connect to the third holes;
wherein the plasma generator is configured to generate ions that form a plasma and are removed by the ion blocker, such that radicals in the plasma are supplied to the treating space through the plurality of first fluid passages and the plurality of third holes,
wherein the inner zone is configured to receive a first gas which is supplied to the treating space through the plurality of first holes,
wherein the outer zone is configured to receive a second gas which is supplied to the treating space through the plurality of second holes.

13. The substrate treating apparatus of claim 12, wherein the plurality of first fluid passages is connected to the distributor.

14. The substrate treating apparatus of claim 12, wherein the partitioning wall has:
a plurality of fourth holes at a bottom thereof; and
a plurality of second fluid passages therein and respectively connected to the fourth holes, wherein the plurality of second fluid passages is between the ion blocker and the plurality of fourth holes and are further connected to the distributor.

15. The substrate treating apparatus of claim 12, wherein the first gas and the second gas are borazine (B₃N₃H₆).

16. The substrate treating apparatus of claim 15, wherein in the chamber, the first gas and the second gas react with radicals to produce amorphous boron nitride (a-BN).

17. The substrate treating apparatus of claim 12, further comprising a heat exchange plate on top of the ion blocker,
wherein the heat exchange plate includes a heat exchanger configured to control a temperature of fluid passing through the heat exchange plate.

18. The substrate treating apparatus of claim 12, wherein the inner zone receives the first gas through a first line connected to a first gas supply,
wherein a first inlet of the first line is connected to a first manifold on top of the ion blocker,
wherein the first manifold is connected to a plurality of first branch pipes extending through the ion blocker and connected to the inner zone,
wherein the outer zone receives the second gas through a second line connected to a second gas supply,
wherein a second inlet of the second line is connected to a second manifold on top of the ion blocker,
wherein the second manifold is connected to a plurality of second branch pipes extending through the ion blocker and connected to the outer zone.

19. A substrate treating apparatus comprising:
a showerhead including an inner zone, an outer zone, and a partitioning wall therebetween and configured to isolate the inner zone and the outer zone from each other; and
a first plate on top of the showerhead and including a distributor; and
a chamber under the showerhead, wherein a substrate support unit configured to support a substrate is in the chamber, and a treating space configured to treat the substrate therein is in the chamber,
a plurality of first holes in the inner zone,
a plurality of second holes in the outer zone,
a plurality of columns in each of the inner zone and the outer zone, wherein each of the plurality of columns extend toward the first plate and has a third hole and a first fluid passage connected to the third hole defined therein,
wherein treating space is configured to receive radicals supplied through the first fluid passage and the third hole,
wherein the treating space is configured to receive borazine (B₃H₆N₃) supplied through the plurality of first holes and the plurality of second holes,
wherein in the treating space, in use, the borazine and the radicals react each other to produce amorphous boron nitride (a-BN).

20. The substrate treating apparatus of claim 19, wherein the partitioning wall comprises:
a plurality of fourth holes at a bottom thereof; and
a plurality of second fluid passages therein and respectively connected to the plurality of fourth holes, wherein the plurality of second fluid passages is located between the first plate and the plurality of fourth holes and are further connected to the distributor.
